(19) United States
(12) Patent Application Publication
(10) Pub. No.: US 2025/0048723 A1
(43) Pub. Date: Feb. 6, 2025

(54) SEMICONDUCTOR DEVICE

(71) Applicant: Samsung Electronics Co., Ltd., Suwon-si (KR)

(72) Inventors: Jinwoo LEE, Suwon-si (KR); Sutae KIM, Suwon-si (KR)

(73) Assignee: Samsung Electronics Co., Ltd., Suwon-si (KR)

(21) Appl. No.: 18/645,844

(22) Filed: Apr. 25, 2024

(30) Foreign Application Priority Data
Jul. 31, 2023 (KR) 10-2023-0099755

(51) Int. Cl. H01L 27/088; H01L 23/48; H01L 29/417; H01L 29/423; H01L 29/775; H01L 29/786

(52) U.S. Cl. CPC H01L 27/088; H01L 23/481; H01L 29/41733; H01L 29/42392; H01L 29/775; H01L 29/78696

(57) ABSTRACT

A semiconductor device includes a substrate having first and second surfaces; an active pattern extending on the first surface of the substrate, the active pattern having first and second conductivity-type impurity regions, the first and second conductivity-type impurity regions in contact with each other; semiconductor patterns stacked on a portion of the active pattern between the first and second conductivity-type impurity regions; an inactive gate structure extending across the portion of the active pattern between the first and second conductivity-type impurity regions, the inactive gate structure surrounding the semiconductor patterns; a first contact passing through the substrate from the second surface of the substrate and connected to the first conductivity-type impurity region; and a second contact passing through the substrate from the second surface of the substrate and connected to the second conductivity-type impurity region.

### CROSS-REFERENCE TO RELATED APPLICATION(S)

This application claims benefit of priority under 35 U.S.C. § 119 to Korean Patent Application No. 10-2023-0099755 filed on Jul. 31, 2023 in the Korean Intellectual Property Office, the disclosure of which is incorporated herein by reference in its entirety.

### BACKGROUND

The present disclosure relates to semiconductor devices.

As demand for implementation of high performance, high speed, and/or multifunctionality of semiconductor devices increases, a degree of integration of semiconductor devices has been increasing. To overcome limitations of operating properties due to a reduction in size of a planar metal oxide semiconductor FET (MOSFET), efforts have been made to develop a semiconductor device including a gate-all-around-type field effect transistor including a finFET including a fin-type channel and nanosheets surrounded by a gate.

### SUMMARY

Example embodiments of the inventive concepts provide a semiconductor device having improved electrical properties and reliability.

Example embodiments of the inventive concepts provide a semiconductor device that includes a substrate having a first surface and a second surface opposing the first surface; an active pattern on the first surface of the substrate, the active pattern extending in a first direction, the active pattern having a first conductivity-type impurity region and a second conductivity-type impurity region arranged along the first direction, the first conductivity-type impurity region and the second conductivity-type impurity region contacting each other; semiconductor patterns stacked on a portion of the active pattern between the first and second conductivity-type impurity regions of the active pattern, the semiconductor patterns spaced apart from each other in a vertical direction; an inactive gate structure extending across the portion of the active pattern between the first and second conductivity-type impurity regions of the active pattern in a second direction, the second direction intersecting the first direction, and the inactive gate structure surrounding the semiconductor patterns; a first contact passing through the substrate from the second surface of the substrate, the first contact connected to the first conductivity-type impurity region; and a second contact passing through the substrate from the second surface of the substrate, the second contact connected to the second conductivity-type impurity region.

Example embodiments of the inventive concept further provide a semiconductor device that includes a substrate having a first surface and a second surfaces opposing the first surface; an active pattern extending on first surface of the substrate, the active pattern extending in a first direction, the active pattern having a first conductivity-type impurity region and a second conductivity-type impurity region arranged along the first direction, the first conductivity-type impurity region and the second conductivity-type impurity region contacting each other; semiconductor patterns stacked on a portion of the active pattern between the first and second conductivity-type impurity regions, the semiconductor patterns spaced apart from each other in a vertical direction; an inactive gate structure extending across the portion of the active pattern between the first and second conductivity-type impurity regions in a second direction, the second direction intersecting the first direction, and the inactive gate structure surrounding the semiconductor patterns; a first conductivity-type epitaxial pattern and a second conductivity-type epitaxial pattern respectively on both side surfaces of the semiconductor patterns in the first direction, the first conductivity-type epitaxial pattern and the second conductivity-type epitaxial pattern respectively on the first conductivity-type impurity region and the second conductivity-type impurity region of the active pattern; an interlayer insulating layer on the first surface of the substrate, the interlayer insulating layer covering the first conductivity-type epitaxial pattern and the second conductivity-type epitaxial pattern; a first contact passing through the interlayer insulating layer, the first contact connected to the first conductivity-type epitaxial pattern; and a second contact passing through the substrate from the second surface of the substrate, the second contact connected to the second conductivity-type impurity region of the active pattern.

Example embodiments of the inventive concepts still further provide a semiconductor device that includes a substrate having a first surface and a second surface opposing the first surface, the substrate having a first device and a second device respectively on a first device region and a second device region of the first surface of the substrate. The first device may include a first active pattern extending on the first surface of the substrate in a first direction; first semiconductor patterns stacked on the first active pattern and spaced apart from each other in a vertical direction; an active gate structure extending across the first active pattern in a second direction, the second direction intersecting the first direction, and the active gate structure surrounding the first semiconductor patterns; a pair of source/drain patterns on both sides of the first semiconductor patterns in the first direction, the pair of source/drain patterns respectively connected to both sides of the first semiconductor patterns; and a gate structure extending in the second direction, the gate structure surrounding the first semiconductor patterns. The second device may include a second active pattern extending on the first surface of the substrate in the first direction, the second active pattern having a first conductivity-type impurity region and a second conductivity-type impurity region arranged in the first direction, the first conductivity-type impurity region and the second conductivity-type impurity region contacting each other; second semiconductor patterns stacked on a portion of the second active pattern between the first and second conductivity-type impurity regions of the second active pattern, the second semiconductor patterns spaced apart from each other in the vertical direction; an inactive gate structure extending across the portion of the second active pattern between the first and second conductivity-type impurity regions of the second active pattern, the inactive gate structure surrounding the second semiconductor patterns; and a first contact and a second contact respectively connected to the first conductivity-type impurity region and the second conductivity-type impurity region. At least one of the first and second contacts is respectively connected to the first and second conductivity-type impurity regions from the second surface of the substrate.

### BRIEF DESCRIPTION OF DRAWINGS

The above and other aspects, features, and advantages of the inventive concepts will be more clearly understood from the following detailed description, taken in conjunction with the accompanying drawings, in which:

FIG. 1 is a plan view of a semiconductor device according to some example embodiments of the inventive concepts;

FIG. 2 is a cross-sectional view of a first device region A of the semiconductor device of FIG. 1, taken along line I-I′;

FIGS. 3A and 3B are cross-sectional views of the first device region A of the semiconductor device of FIG. 1, taken along lines II1-II1′ and II2-II2′;

FIG. 4 is a cross-sectional view of a second device region B of the semiconductor device of FIG. 1, taken along line III-III′;

FIGS. 5A and 5B are cross-sectional views of the second device region B of the semiconductor device of FIG. 1, taken along lines IV1a-IV1a′ and IV2b-IV2b′;

FIGS. 6A and 6B are cross-sectional views of the second device region B of the semiconductor device of FIG. 1, taken along lines IV2a-IV2a′ and IV1b-IV1b′;

FIGS. 7, 8A, 8B, 9A, and 9B are cross-sectional views of a semiconductor device according to some example embodiments of the inventive concepts;

FIGS. 10, 11A, and 11B are cross-sectional views of a semiconductor device according to some example embodiments of the inventive concepts;

FIGS. 12, 13A, and 13B are cross-sectional views of a semiconductor device according to some example embodiments of the inventive concepts;

FIGS. 14, 15A, and 15B are cross-sectional views of a semiconductor device according to some example embodiments of the inventive concepts; and

FIGS. 16, 17A, and 17B are cross-sectional views of a semiconductor device according to some example embodiments of the inventive concepts.

### DETAILED DESCRIPTION

Hereinafter, various example embodiments of the inventive concepts will be described in detail with reference to the accompanying drawings.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

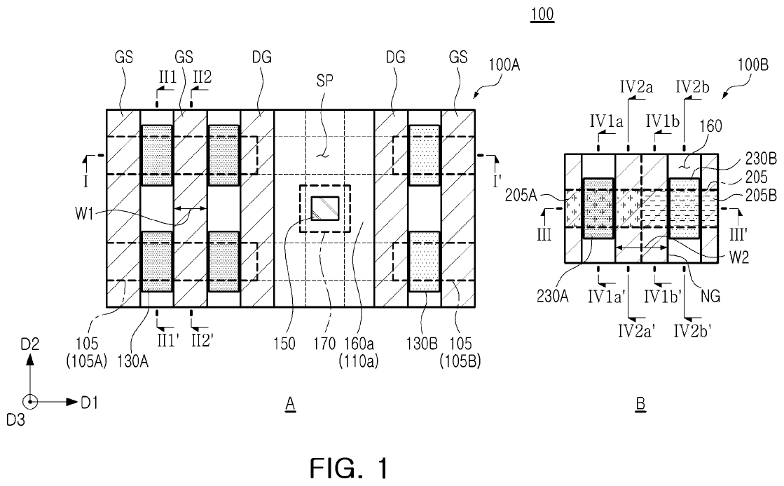

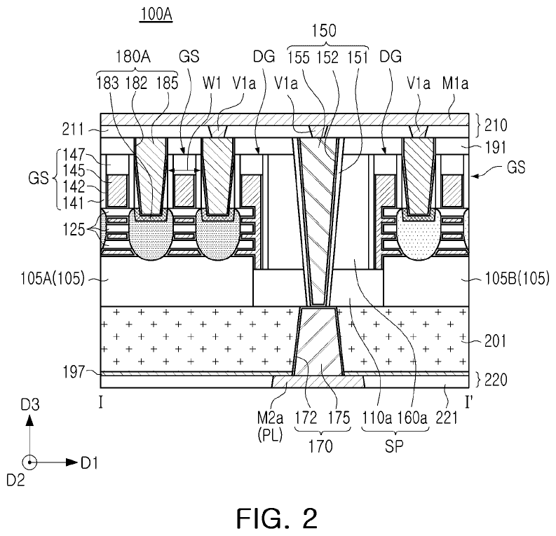

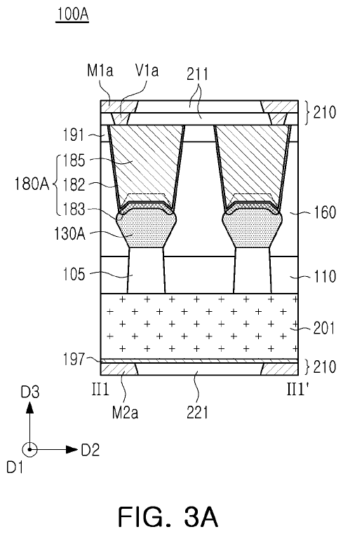

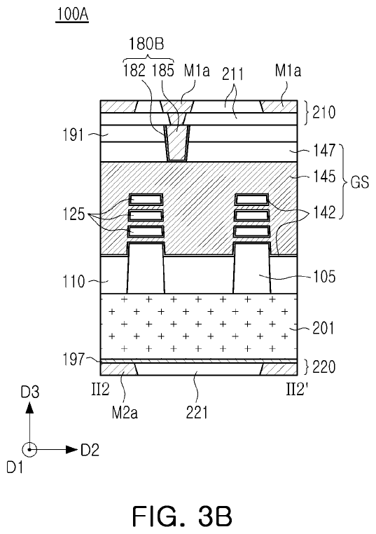

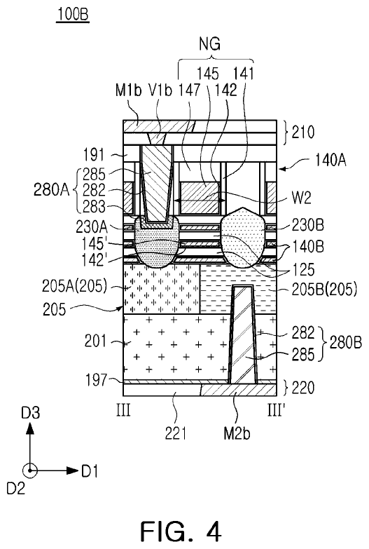

FIG. 1 is a plan view of a semiconductor device according to some example embodiments of the inventive concepts. FIG. 2 is a cross-sectional view of a first device region A of the semiconductor device of FIG. 1, taken along line I-I′. FIGS. 3A and 3B are cross-sectional views of the first device region A of the semiconductor device of FIG. 1, taken along lines II1-II1′ and II2-II2′. FIG. 4 is a cross-sectional view of a second device region B of the semiconductor device of FIG. 1, taken along line III-III′.

First, referring to FIGS. 1, 2, and 4, a semiconductor device 100 according to some example embodiments may have a first device region A and a second device region B arranged in a horizontal direction (for example, an X-direction or Y-direction). The first device region A may also be referred to as a “logic region” in which logic devices 100A are formed, and the second device region B may also be referred to as a “peripheral circuit region” in which passive devices 100B are formed.

Referring to FIGS. 2, 3A, and 3B together with FIG. 1, the logic device 100A of the semiconductor device 100 according to some example embodiments may include a substrate 201, a plurality of active patterns 105 extending on the first device region A of the substrate 201 in a first direction (for example, a direction of D1), and a separation pattern SP separating each of the plurality of active patterns 105 into first and second active patterns 105A and 105B.

The semiconductor device 100 according to some example embodiments may further include gate structures GS crossing the first and second active patterns 105A and 105B and extending in the second direction (for example, a direction of D2), a dummy gate structure DG extending in the second direction (for example, a direction of D2) along ends of the plurality of first and second active patterns 105 from both sides of the separation pattern SP, and first and second source/drain patterns 130A and 130B disposed on the first and second active patterns 105A and 105B on both sides of the gate structure GS. Here, the gate structure GS may also be referred to as an “active gate structure” included in a transistor, and the dummy gate structure DG may also be referred to as an “inactive gate structure” not included in the transistor.

The substrate 201 according to some example embodiments may include an insulating material layer prepared after removing a semiconductor substrate used to form devices (for example, 100A and 100B). In some example embodiments, the substrate 201 may include an oxide layer. For example, the substrate 201 may be formed of flowable oxide (FOX), Tonen silazene (TOSZ), undoped silica glass (USG), borosilica glass (BSG), phosphosilica glass (PSG), borophosphosilica glass (BPSG), high density plasma (HDP) oxide, plasma enhanced oxide (PEOX), flowable CVD (FCVD) oxide, or combinations thereof. The substrate 201 may be formed using a chemical vapor deposition (CVD) process, a flowable-CVD process, or a spin coating process.

The active pattern 105 may have a fin-type structure protruding from the insulating substrate 201 in a third direction (for example, a direction of D3) and extending in a first direction (for example, a direction of D1). The active pattern 105 may be a pattern obtained by partially etching a semiconductor substrate. However, as described above, the active pattern 105 may have a structure obtained by removing a portion of the semiconductor substrate below the active pattern 105. Accordingly, the active pattern 105 according to some example embodiments may include a semiconductor material the same as that of the semiconductor substrate. For example, the active pattern 105 may include a semiconductor such as Si or Ge, or a compound semiconductor such as SiGe, SiC, GaAs, InAs, or InP. In some example embodiments, the active pattern 105 may be an N-type impurity region for a P-MOS transistor or a P-type impurity region for an N-MOS transistor, but the inventive concepts are not limited thereto.

The device isolation layer 110 may be disposed on the insulating substrate 201 to define the active pattern 105. For example, the device isolation layer 110 may include silicon oxide or a silicon oxide-based insulating material. The device isolation layer 110 may be a trench isolation, defining the active pattern 105.

Referring to FIGS. 1, 2, 3A and 3B, the active pattern 105 may have a fin-type structure extending from a first surface of the insulating substrate 201 in the first direction (for example, a direction of D1). A plurality of semiconductor patterns 125 may be disposed on the active pattern 105 to be spaced apart from each other in a direction, perpendicular to the first surface of the insulating substrate 201, that is, a third direction (for example, a direction of D3). The active pattern 105 and the plurality of semiconductor patterns 125 may be provided as a multichannel layer of a transistor. In some example embodiments, the number of the plurality of semiconductor patterns 125 is exemplified as three, but the number thereof is not particularly limited. For example, the plurality of semiconductor patterns 125 may include silicon (Si) or silicon germanium (SiGe).

As illustrated in FIG. 1, the logic device 100A according to some example embodiments may include a plurality of gate structures GS extending in the second direction (for example, a direction of D2). As described above, the plurality of gate structures GS may be arranged to respectively intersect the first and second active patterns 105A and 105B separated in the first direction (for example, D1 direction) by the separation pattern SP.

Referring to FIGS. 2 and 3B, the gate structure GS may include gate spacers 141, a gate insulating film 142 and a gate electrode 145 sequentially disposed between the gate spacers 141, and a gate capping layer 147 disposed on the gate electrode 145. For example, the gate spacers 141 may include an insulating material such as SiOCN, SiON, SiCN, or SiN. The gate insulating film 142 may be formed of, for example, a silicon oxide film, a high-κ dielectric film, or a combination thereof. The high-κ dielectric film may include a material having a dielectric constant (for example, about 10 to 25) higher than that of the silicon oxide film. For example, the high-κ dielectric film may include a material selected from hafnium oxide, hafnium oxynitride, hafnium silicon oxide, lanthanum oxide, lanthanum aluminum oxide, and combinations thereof, but the inventive concepts are not limited thereto. The gate electrode 145 may include a conductive material, for example, a metal nitride such as titanium nitride (TiN), tantalum nitride (TaN), or tungsten nitride (WN), and/or a metal material such as aluminum (Al), tungsten (W), or molybdenum (Mo) or a semiconductor material such as doped polysilicon. In some example embodiments, the gate electrode 145 may be a multilayer including two or more films. The gate capping layer 147 may include, for example, silicon nitride, silicon oxynitride, silicon carbonitride, or silicon oxycarbonitride.

The logic device 100A according to some example embodiments may be arranged according to the separation pattern SP, and may include power transmission structures for supplying power to each transistor cell from a second surface of the insulating substrate 201, that is, a rear surface. The power transmission structures according to some example embodiment may include a buried conductive structure 150 arranged on the separation pattern SP in the second direction (for example, a direction of D2), and conductive through-structures 170 extending from the second surface of the substrate 201 toward the first surface, the conductive through-structures 170 connected to the buried conductive structure 150.

In some example embodiments, as illustrated in FIG. 2, the buried conductive structures 150 may extend to the first surface of the insulating substrate 201, and the power transmission structure 170 may pass through the insulating substrate 201 to be respectively in contact with bottom surfaces of the buried conductive structures 150 from the first surface of the insulating substrate 201. The conductive through-structures 170 may receive power from a second interconnection line M2a, positioned on the second surface of the insulating substrate 201, and may supply power to source/drain patterns 130A and 130B of the logic device 100A through the buried conductive structure 150. In some example embodiments, the buried conductive structures 150 may be electrically connected to the source/drain patterns 130A and 130B through a first interconnection line M1a, a power line of a first interconnection structure 210.

The buried conductive structure 150 may include a conductive material 155 and a conductive barrier 152 surrounding bottom and side surfaces of the conductive material 155. In some example embodiments, the buried conductive structure 150 may further include an insulating liner 151, surrounding the conductive barrier 152. The conductive through-structure 170 may include a conductive material 175 and a conductive barrier 172 surrounding bottom and side surfaces of the conductive material 175.

For example, the conductive materials 155 and 175 may include Cu, Co, Mo, Ru, W, or alloys thereof. In some example embodiments, the conductive materials 155 and 175 may include different conductive materials. For example, the conductive barriers 152 and 172 may include Ta, TaN, Mn, MnN, WN, Ti, TiN, or combinations thereof. For example, the insulating liner 151 may include SiO₂, SiN, SiCN, SiC, SiCOH, SION, Al₂O₃, AlN, or combinations thereof.

In some example embodiments, the dummy gate structure DG, positioned on both sides of the isolation pattern SP, may include components similar to those of the gate structure GS. Each of the dummy gate structures DG may include gate spacers 141, a gate insulating film 142, a gate electrode 145, and a gate capping layer 147. However, as described above, the dummy gate structure may be positioned at ends of the first and second active patterns 105A and 105B. Accordingly, as illustrated in FIG. 2, a portion of the dummy gate structure DG may extend to the device isolation layer 110 along cross-sections of the first and second active patterns 105A and 105B.

The first and second source/drain patterns 130A and 130B according to some example embodiments may be disposed on regions of the first and second active patterns 105A and 105B, positioned on both sides of the gate structure GS. The first and second source/drain patterns 130A and 130B may be respectively connected to both ends of the plurality of semiconductor patterns 125 in the first direction (for example, a direction of D1). The gate electrode 145 may have a portion 145′ extending in the second direction (for example, a direction of D2) to intersect the first and second active patterns 105A and 105B and surrounding the plurality of semiconductor patterns 125. The gate insulating film 142 may also have a portion 142′ extending between the plurality of semiconductor patterns 125 and the gate electrode portion 145′. As described above, the semiconductor device 100 according to some example embodiments may be included in a gate-all-around-type field effect transistor.

The first and second source/drain patterns 130A and 130B may include an epitaxial pattern selective epitaxially grown (SEG) from recessed surfaces of the first and second active patterns 105A and 105B and side surfaces of the plurality of semiconductor patterns 125 at both sides of the gate structure GS. For example, the first and second source/drain patterns 130A and 130B may be Si, SiGe, or Ge, and may have an N-type or P-type conductivity. In some example embodiments, when the first source/drain patterns 130A are N-type source/drains, the first source/drain patterns 130A may include silicon (Si) doped with N-type impurities such as phosphorus (P), nitrogen (N), arsenic (As), and/or antimony (Sb). When the second source/drain patterns 130B are P-type sources/drains, the second source/drain patterns 130B may include silicon (Si) or silicon germanium (SiGe) doped with P-type impurities such as boron (B), indium (In), gallium (Ga), and/or boron trifluoride (BF₃).

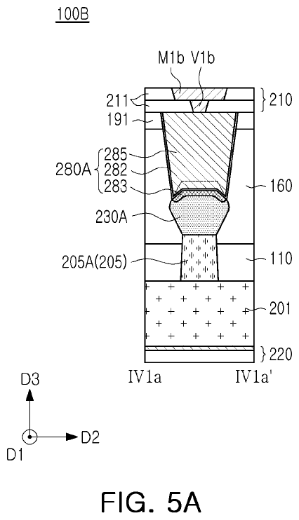

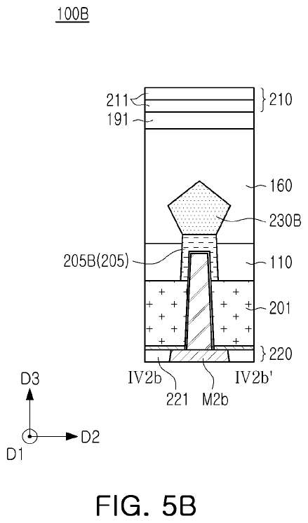

The first and second source/drain patterns 130A and 130B may have different shapes along crystallographically stable surfaces during growth. For example, the N-type first source/drain patterns 130A may have a hexagonal cross-section or a polygonal cross-section having gentle angles (see FIG. 3A), and the P-type second source/drain patterns 130B may have a pentagonal cross-section (see FIG. 5b).

As described above, the semiconductor device 100 according to some example embodiments may have the first device region A and the second device region B, arranged in different regions in a horizontal direction. The second device region B may include a passive device 100B, included in a peripheral circuit. The passive device 100B according to some example embodiments may be formed through a series of processes combined with the process of forming the logic device 100A described above, and thus a correlation between respective components may be present.

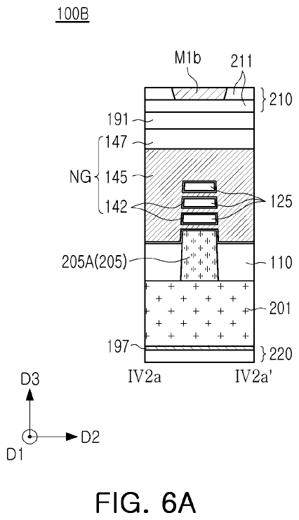

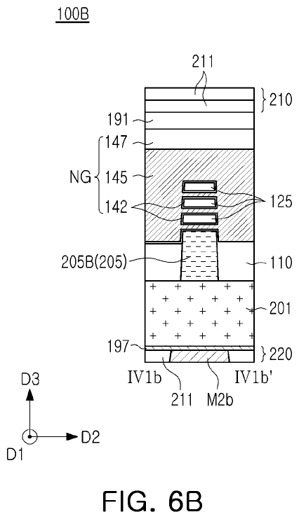

FIG. 4 is a cross-sectional view of a second device region B of the semiconductor device of FIG. 1, taken along line III-III′. FIGS. 5A and 5B are cross-sectional views of the second device region B of the semiconductor device of FIG. 1, taken along lines IV1a-IV1a′ and IV2b-IV2b′. FIGS. 6A and 6B are cross-sectional views of the second device region B of the semiconductor device of FIG. 1, taken along lines IV2a-IV2a′ and IV1b-IV1b′.

Referring to FIGS. 4, 5A, 5B, 6A, and 6B, the passive device 100B of the semiconductor device 100 according to some example embodiments may include an active pattern 205 disposed on the second device region B of the substrate 201 in a first direction (for example, a direction of D1), semiconductor patterns 125 stacked on a portion of the active pattern 205 and spaced apart from each other in a vertical third direction (for example, a direction of D3), an inactive gate structure NG extending in a second direction (for example, a direction of D2) and surrounding the semiconductor patterns 125, and a first conductivity-type epitaxial pattern 230A and a second conductivity-type epitaxial pattern 230B respectively disposed on both side surfaces of the semiconductor patterns 125 on both sides of the inactive gate structure NG.

The active pattern 205 of the passive device 100B may have a first conductivity-type impurity region 205A and a second conductivity-type impurity region 250B in contact with each other. The first and second conductivity-type impurity regions 205A and 205B may be provided as impurity regions included in a passive device. For example, the first and second conductivity-type impurity regions 205A and 205B may be formed using a selective ion implantation process on the active pattern 205 (for example, the second device region B of the semiconductor substrate) of the passive device 100A.

As illustrated in FIG. 4, the semiconductor patterns 125 may be stacked on a contact portion between the first and second conductivity-type impurity regions 205A and 205B of the active pattern 250, that is, on a bonding interface, and spaced apart from each other in a vertical direction. In some example embodiments, the bonding interface between the first and second conductivity-type impurity regions 205A and 205B may extend substantially vertically from an upper surface to a lower surface of the active pattern 205.

The inactive gate structure NG may be positioned on a contact portion between the first and second conductivity-type impurity regions 205A and 205B of the active pattern 205.

Each of a plurality of inactive gate structures NG may be a structure corresponding to the gate structure GS, but may be understood as a dummy structure not involved in driving of a device. The plurality of inactive gate structures NG according to some example embodiments may have components similar to those of the gate structure GS of the logic device 100A, and corresponding components may include the same material.

Referring to FIGS. 4, 6A, and 6B together with FIGS. 2 and 3B, each of the plurality of inactive gate structures NG may include a gate electrode 145 surrounding the semiconductor patterns 125, a gate insulating layer 142 between the semiconductor patterns 125 and the gate electrode 145, gate spacers 141 disposed on both sidewalls of a portion of the gate electrode 145 positioned on an uppermost semiconductor pattern, and a gate capping layer 147 disposed on the gate electrode 145 between the gate spacers 141, and may include a material the same as that of corresponding components of the gate structure GS of the second logic device 100A. In some example embodiments, the inactive gate structure NS may have a width W2 in a first direction (for example, a direction of D1), wider than a width W1 of the gate structure GS of the logic device 100A in the first direction.

The semiconductor patterns 125 of the passive device 100B may be layers formed using a process the same as that of the semiconductor patterns 125 of the logic device 100A. The semiconductor patterns 125 of the two devices 100A and 100B may be positioned on the same level, and may include substantially the same semiconductor material. An ion implantation process of forming the impurity regions 205A and 205B in the active pattern 205 may be performed before the semiconductor patterns 125 are formed. In some example embodiments, the semiconductor patterns 125 may remain as a semiconductor layer that is not intentionally doped.

The first conductivity-type epitaxial pattern 230A and the second conductivity-type epitaxial pattern 230B may be respectively disposed on the first conductivity-type impurity region 205A and the second conductivity-type impurity region 205B of the active pattern 205. The first conductivity-type epitaxial pattern 230A and the second conductivity-type epitaxial pattern 230B may be respectively connected to both side surfaces of the semiconductor patterns 125 in the first direction (for example, a direction of D1). For example, the first conductivity-type epitaxial pattern 230A and the first conductivity-type impurity region 205A may be an N-type region, and the second conductivity-type epitaxial pattern 230B and the second conductivity-type impurity region 205B may be a P-type region.

The first conductivity-type epitaxial pattern 230A and the second conductivity-type epitaxial pattern 230B may be formed using a process of forming the first and second source/drain patterns 130A and 130B of the logic device 100A. For example, the first conductivity-type epitaxial pattern 230A may be formed together with the first source/drain patterns 130A. Similarly, the second conductivity-type epitaxial pattern 230B may be formed together with the second source/drain patterns 130B. In some example embodiments, the first conductivity-type epitaxial pattern 230A and the first source/drain patterns 130A may be N-type epitaxial patterns having the same composition. The second conductivity-type epitaxial pattern 230B and the second source/drain patterns 130B may be P-type epitaxial patterns having the same composition. Such a process may be performed by a selective epitaxial growth (SEG) process, as described above. However, a distribution (variation in quality and size) of a grown epitaxial may exist depending on a state of each crystal plane or the like on which the epitaxial is grown. The first conductivity-type epitaxial pattern 230A and the second conductivity-type epitaxial pattern 230B have their own resistance in addition to resistance occurring at an interface with the first and second conductivity-type impurity regions 205A and 205B. Due to such a resistance element, a diode component between the first and second conductivity-type epitaxial patterns 230A and 230B may have relatively a high operating voltage and a high probability of occurrence of a distribution.

In order to address such an issue, in some example embodiments, there may be proposed a scheme of omitting one of the first conductivity-type epitaxial pattern 230A and the second conductivity-type epitaxial pattern 230B from an electrical path of a diode that is being driven. The scheme may be implemented by adjusting arrangements of a first contact 280A and a second contact 280B.

For example, referring to FIGS. 4, 5A and 5B, the first contact 280A may pass through an interlayer insulating layer 160 to be connected to the first conductivity-type epitaxial pattern 230A, whereas the second contact 280B may pass through the insulating substrate 201 to be directly connected to the second conductivity-type impurity region 205B of the active pattern 205 from a second surface (that is, a lower surface) of the insulating substrate 201. Unlike the first contact 280A, the second contact 280B may be directly connected to the second conductivity-type impurity region 205B without passing through the second conductivity-type epitaxial pattern 230B, such that an operating voltage of the passive device 100B may be reduced by an amount of a resistance element of the second conductivity-type epitaxial pattern 230B.

The second contact 280B according to some example embodiments may be formed during a series of backside processes, such as a process of forming the conductive through-structure 170 and a process of forming a second interconnection structure 220, after a front-side process of forming the logic device 100A and the passive device 100B on the semiconductor substrate is performed.

For example, each of the first and second contacts 280A and 280B may include a conductive material 285 and a conductive barrier 282 surrounding a side surface and a bottom surface of the conductive material 285. In some example embodiments, the first contact 280A may include a metal-semiconductor compound layer film 283 formed on the first conductivity-type epitaxial patterns 230A to improve contact resistance. The metal-semiconductor compound layer 283 may be formed on a surface of the first conductivity-type epitaxial pattern 230A on the outside of the conductive barrier 282. For example, the conductive material 282 may include Cu, Co, Mo, Ru, W, or alloys thereof. For example, the conductive barrier 282 may include Ta, TaN, Mn, MnN, WN, Ti, TiN, or combinations thereof. For example, the metal-semiconductor compound layer 283 may include at least one of titanium-silicide, tantalum-silicide, tungsten-silicide, nickel-silicide, and cobalt-silicide.

The semiconductor device 100 according to some example embodiments may further include first and second source/drain patterns 130A and 130B in the first device region A, and an interlayer insulating layer 160 disposed on the device isolation layer 110 to cover the first and second conductivity-type epitaxial patterns 230A and 230B in the second device region B. For example, the interlayer insulating layer 160 may include FOX, TOSZ, USG, BSG, PSG, BPSG, PETEOS, FSG, HDP oxide, PEOX, FCVD oxide, or combinations thereof. The interlayer insulating layer 160 may be formed using a chemical vapor deposition process, a flowable CVD process, or a spin coating process. The semiconductor device 100 according to some example embodiments may further include an intermediate insulating layer 191 covering the interlayer insulating layer 160 and the gate structures GS, DG, and NG. The intermediate insulating layer 191 may include an insulating material similar to that of the interlayer insulating layer 160.

Referring to FIGS. 2 and 4, the source/drain contact 180A and the first contact 280A may pass through not only the interlayer insulating layer 160 but also the intermediate insulating layer 191 to be respectively connected to the first and second source/drain patterns 130A and 130B and the first conductivity-type epitaxial pattern 230A. Referring to FIG. 3B, the gate contact 180B may pass through the intermediate insulating layer 191 and the gate capping layer 147 to be connected to the gate electrode 145.

In a similar manner to the first and second contacts 280A and 280B, the source/drain contact 180A and the gate contact 180B may include a conductive material 185 and a conductive barrier 182 surrounding a side surface and an end surface of the conductive material 185. For example, the conductive material 185 may include Cu, Co, Mo, Ru, W, or alloys thereof. For example, the conductive barrier 182 may include Ta, TaN, Mn, MnN, WN, Ti, TiN, or combinations thereof. In some example embodiments, the source/drain contact 180A may include a metal-semiconductor compound layer 183 formed on the first and second source/drain patterns 130A and 130B to improve contact resistance.

The semiconductor device 100 according to some example embodiments may have a double-sided interconnection structure including an upper interconnection structure 210 and a lower interconnection structure 220. The double-sided interconnection structure may be applied across the first and second device regions A and B, and may be configured to electrically connect the logic devices 100A and the passive devices 100B to each other. The upper interconnection structure 210 may be provided on an upper surface of the semiconductor device 100, and the lower interconnection structure 220 may be provided on a lower surface of the semiconductor device 100.

In some example embodiments, the upper interconnection structure 210 may include a plurality of (for example, two) upper insulating layers 211, and first and second upper metal lines M1a and M1b and first and second upper vias V1a and V1b, formed in the upper insulating layer 211. For example, each of interconnection layers (indicating a combination of respective metal lines and associated vias) may be formed using a dual damascene process. An upper interconnection layer, positioned in the first device region A, may include the first upper metal line M1a and the first upper vias V1a, and an upper interconnection layer, positioned in the second device region B, may include the second upper metal line M1b and second upper vias V1b. The upper interconnection layers may be configured such that the logic device 100A and the passive device 100B are connected to each other.

An insulating protective film (or etch stop film) 197 may be disposed on a second surface (or lower surface) of the insulating substrate 201. The insulating protective film 197 may be provided to surround a contact region of the conductive through structure 170, protruding from the second surface of the insulating substrate 201. The lower interconnection structure 220 may be disposed on the insulating protective film 197. The lower interconnection structure 220 may include a lower insulating layer 221 and first and second lower metal lines M2a and M2b, formed in the lower insulating layer 221. The first lower metal line M2a may be provided as a power line connected to the conductive through structure 170. The second lower metal line M2b may be provided as a signal line connected to the second contact 280B. In some example embodiments, the lower interconnection structure 220, positioned in the second device region B, may further include an additional interconnection layer, and may be configured such that the logic device 100A and the passive device 100B are connected to each other, together with supply of a power line. In some example embodiments, the insulating protective film 197 and the first and second insulating layers 211 and 221 may include different insulating materials. For example, the insulating protective film 197 may include AlN or SiN, and the upper and lower insulating layers 211 and 221 may include SiO₂.

As in some example embodiments, at least one contact, among the first and second contacts 280A and 280B of the passive device 100B, may be changed to have a backside contact structure to be directly connected to the first or second conductivity-type impurity region 205A or 205B. Such a change may limit and/or prevent adverse effects (for example, a resistance element and a distribution) of the first or second conductivity-type epitaxial patterns 230A or 230B, causing various resistance elements, thereby reducing an operating voltage of the passive device 100B and greatly improving a distribution of the operating voltage.

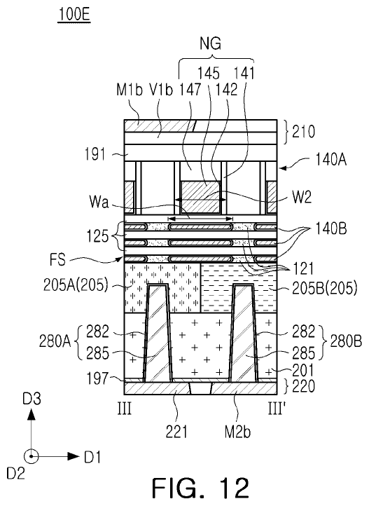

The inventive concepts may be implemented in various modified example embodiments. For example, a scheme of improving resistance by changing at least one contact to have a backside contact structure may also be advantageously implemented in passive devices having various structures. An operating voltage and a distribution may be greatly improved by changing both the first and second contacts to have a backside contact structure (see FIGS. 12, 14, and 16). In some example embodiments, a conductivity-type epitaxial pattern may be omitted.

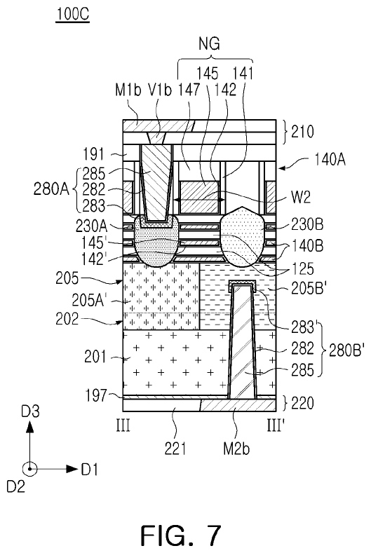

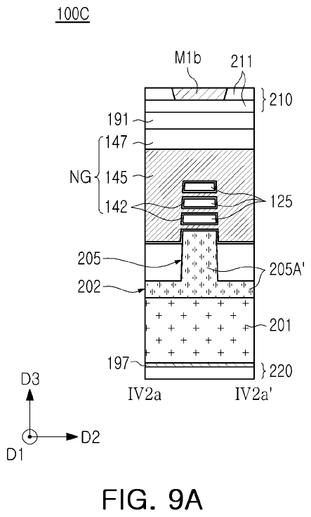

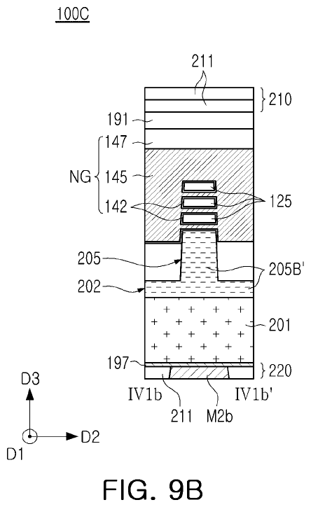

FIGS. 7, 8A, 8B, 9A, and 9B are cross-sectional views of a semiconductor device according to some example embodiments of the inventive concepts.

Referring to FIGS. 7, 8A, 8B, 9A, and 9B, a passive device 100C according to some example embodiments may be understood as being similar to the passive device 100B illustrated in FIGS. 1, 4, 5A, 5B, 6A, and 6B, except that an active region 202, having a desired (and/or predetermined) area, is present below the active pattern 205, and a metal-semiconductor compound layer 283′ is disposed on an upper end of a second contact 280B′. Other components of may be understood with reference to descriptions of the same or similar components of the passive device 100B illustrated in FIGS. 1, 4, 5A, 5B, 6A, and 6B, unless otherwise described.

The passive device 100C according to some example embodiments may further have an active region 202, having a desired (and/or predetermined area), below the active pattern 205. The first and second conductivity-type impurity regions 205A and 205B of the active pattern 205 may respectively extend to corresponding regions of the active region 202 in a vertical downward direction. In the present example embodiment, extending first and second conductivity-type impurity regions 205A′ and 205B′ may have a region extending in a vertical direction to correspond to a thickness of the active region. Accordingly, the second contact 280B′, having a backside contact structure, may be relatively easily formed. The second contact 280B′ may extend from a second surface of the substrate 201, and may be selected such that an end thereof is positioned within the active region 202 or the active pattern 205.

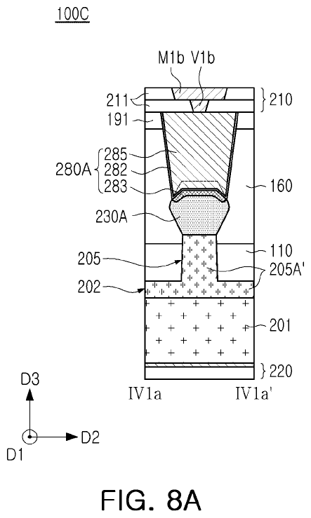

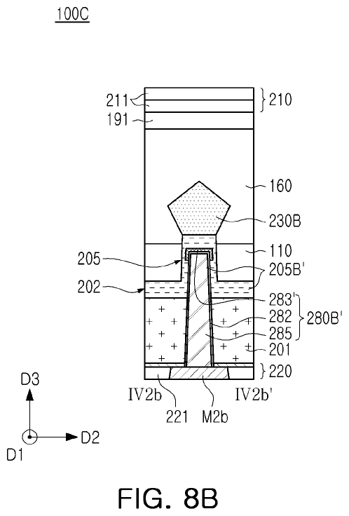

Referring to FIGS. 8A and 8B, the active pattern 205 may have a structure extending on the active region 202 in a first direction (for example, a direction of D1). The active region 202 may be understood as a structure provided from a portion of a semiconductor substrate (not illustrated). For example, in a manufacturing process, first and second conductivity-type impurity regions 205A′ and 205B′, having a first depth, may be formed in the semiconductor substrate using an ion implantation process, and the active pattern 205, having a height lower than the first depth, may be formed by patterning an ion-implanted region. The active region 202 may be a structure obtained by subsequently removing at least a portion of the active pattern 205 in which the impurity regions 205A′ and 205B′ are not formed from a lower surface of the semiconductor substrate. Such a partial removal process may be performed by a chemical mechanical polishing (CMP) and/or etching process.

In some example embodiments, in a similar manner to the first contact 280A, the second contact 280B may include a metal-semiconductor compound layer 283′ formed on the second conductivity-type impurity region 205B′ to improve contact resistance. The metal-semiconductor compound layer 283′ may be formed on a surface of the second conductivity-type impurity region 205B′ on the outside of the conductive barrier 282. For example, the metal-semiconductor compound layer 283′ may include cobalt silicide (CoSiₓ), nickel silicide (NiSiₓ), or manganese silicide (MnSiₓ), but the inventive concepts are not limited thereto.

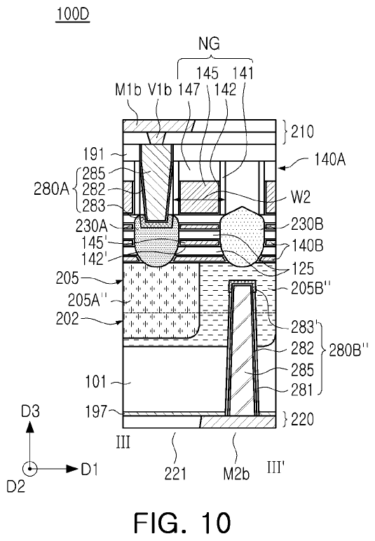

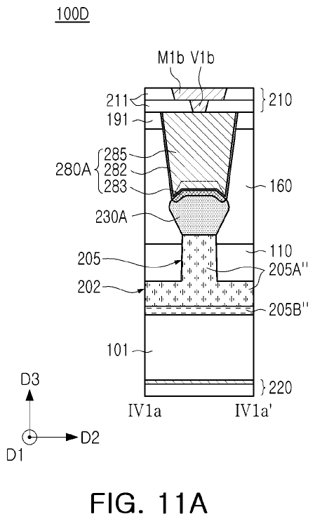

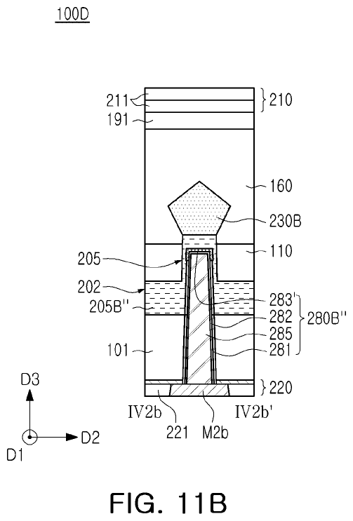

FIGS. 10, 11A, and 11B are cross-sectional views of a semiconductor device according to some example embodiments of the inventive concepts.

Referring to FIGS. 10, 11A, and 11B, a passive device 100D according to some example embodiments may be understood as being similar to the passive device 100B illustrated in FIGS. 1, 4, 5A, 5B, 6A, and 6B, except that the active region 202 and a portion of a semiconductor substrate 101 remain below the active pattern 205, metal-semiconductor compound layer 283′ is disposed on an upper end of an second contact 280B″, and the second contact 280B″ further includes an insulating liner 281 for electrical insulation from the semiconductor substrate 101. Other components may be understood with reference to descriptions of the same or similar components of the passive device 100B illustrated in FIGS. 1, 4, 5A, 5B, 6A, and 6B, unless otherwise described.

In some example embodiments, not only the active region 202 but also another region 101 of the semiconductor substrate, that is, a region 101 of the semiconductor substrate that is not ion-implanted, may remain below the active pattern 205. As described previously described, the remaining semiconductor substrate 101 may be obtained by adjusting a thickness removed during the CMP and/or etching process. In some example embodiments, the remaining semiconductor substrate 101 may replace an insulating substrate (for example, 201 in FIG. 8).

In some example embodiments, the second contact 280B″ may be configured to pass through the semiconductor substrate 101, and thus may further include an insulating liner 281 to provide electrical insulation from the semiconductor substrate 101. The second contact 280B″ may include a conductive plug 285, a conductive barrier 282 covering an upper surface and a side surface of the conductive plug 285, and an insulating liner 281 disposed between the conductive barrier 282 and at least the semiconductor substrate 101. For example, the insulative liner 281 may include SiO₂, SiN, SiCN, SiC, SiCOH, SiON, Al₂O₃, AlN, or combinations thereof. The second contact 280B″ according to some example embodiments may include a metal-semiconductor compound layer 283′ positioned on an upper end thereof, in a similar manner to the previous example embodiment (see FIG. 8).

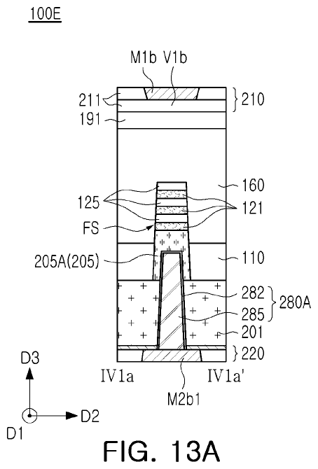

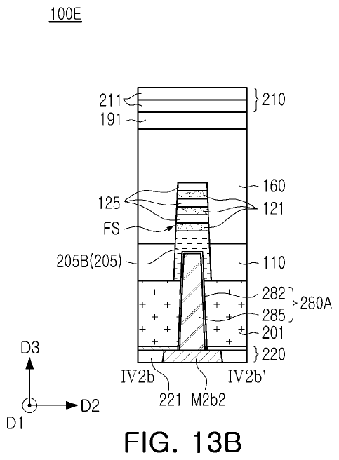

FIGS. 12, 13A, and 13B are cross-sectional views of a semiconductor device according to some example embodiments of the inventive concepts.

Referring to FIGS. 12, 13A, and 13B, a passive device 100E according to some example embodiments may be understood as being similar to the passive device 100B illustrated in FIGS. 1, 4, 5A, 5B, 6A, and 6B, except that the first conductivity-type epitaxial pattern (e.g., 230A of FIG. 7) and the second conductivity-type epitaxial patterns (e.g., 230B of FIG. 7) are omitted, and both the first contact 280A and the second contact 280B extend from a lower surface of the insulating substrate 201. Other components of some example embodiments may be understood with reference to descriptions of the same or similar components of the passive device 100B illustrated in FIGS. 1, 4, 5A, 5B, 6A, and 6B, unless otherwise described.

In some example embodiments, both the first contact 280A and the second contact 280B may have a backside contact structure extending from a second surface (or lower surface) of the insulating substrate 201. In a similar manner to the second contact 280B, the first contact 280A may pass through the insulating substrate 201 to be connected to the first conductivity-type impurity region 205A from the second surface of the insulating substrate 201. Both the first and second contacts 280A and 280B may be directly connected to the first and second conductivity-type impurity regions 205A and 205B, respectively.

In some example embodiments, the first conductivity-type epitaxial patterns 230A and the second conductivity-type epitaxial patterns 230B may be omitted. In a process (a recess process and a selective epitaxial growth process) of forming first and second source/drain patterns (“130A and 130B” in FIGS. 1 and 2) of a logic device (“100A” in FIG. 2), the first and second conductivity-type epitaxial patterns 230A and 230B may be omitted by masking the second device region B in which the passive device 100E is to be formed.

For example, as illustrated in FIGS. 13A and 13B, the passive device 100E according to some example embodiments may include a fin structure FS extending on the active pattern 205 in a first direction (for example, a direction of D1). The fin structure FS may be understood as a structure present in an operation before first and second source/drain patterns (“130A and 130B” in FIGS. 1 and 2) are formed in the entire device region of the semiconductor device (that is, after a dummy gate structure is formed, and before a recess process).

The fin structure FS may have a structure in which a plurality of first semiconductor layers 121 and a plurality of second semiconductor layers 125 are alternately stacked. The plurality of first semiconductor layers 121 may be sacrificial layers that are selectively removable, and the plurality of second semiconductor layers 125 may include a material the same as that of semiconductor patterns (“125” in FIG. 2) used as channels in a logic device (“100A” in FIG. 2). Each of the second semiconductor layers 125 according to some example embodiments may be understood as a layer structure in which the semiconductor patterns 125 of FIG. 2 extend onto the active patterns 205 on both sides of the inactive gate structure NG.

In some example embodiments, the first semiconductor layers 121 and the second semiconductor layers 125 may include semiconductor materials having different compositions. The first semiconductor layers 121 and the second semiconductor layers 125 may have different germanium composition ratios (for example, 0 to 60%). For example, the first semiconductor layers 121 may include silicon germanium, and the second semiconductor layers 125 may include silicon.

Referring to FIG. 12, the inactive gate structure NG may include a first portion 140A positioned on an uppermost semiconductor layer, among the second semiconductor layers 125, and a second portion 140B connected to the first portion 140A and disposed between the first semiconductor layers 121. A width Wa of the second portion 140B of the gate structure NG in a first direction (for example, a direction of D1) may be wider than a width W1 of the first portion 140A of the inactive gate structure NG in the first direction (for example, a direction of D1). Such a form may be understood as a structure formed by additionally removing the second semiconductor layer 125 since first and second conductivity-type epitaxial patterns (“230A and 230B” in FIG. 4), corresponding to a source/drain structure, are not present, when the first semiconductor layer 125, a sacrificial layer, is removed in a process of forming the inactive gate structure NG (that is, the gate structures GS and DS in the logic device 100A of FIG. 2).

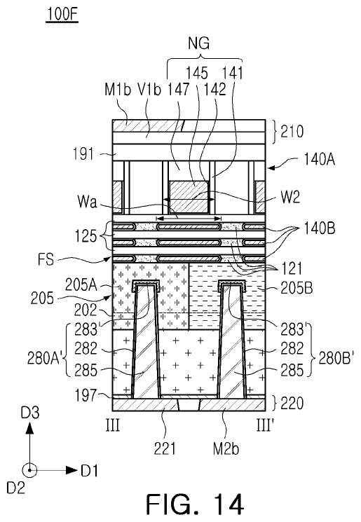

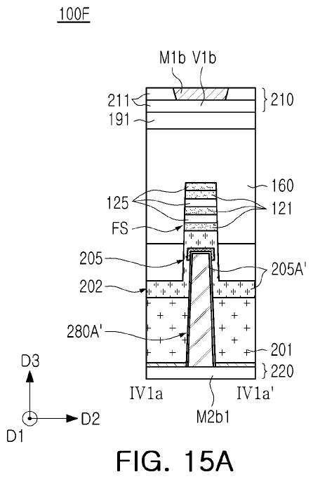

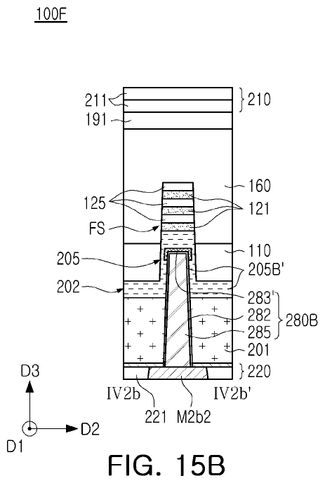

FIGS. 14, 15A, and 15B are cross-sectional views of a semiconductor device according to some example embodiments of the inventive concepts.

Referring to FIGS. 14, 15A, and 15B, a passive device 100F according to some example embodiments may be understood as being similar to the passive device 100E illustrated in FIGS. 12, 13A, and 13B, except that the active region 202, having a desired (and/or predetermined) area, is present below the active pattern 205, and the metal-semiconductor compound layer 283′ is disposed on an upper end of the second contact 280B′. Other components may be understood with reference to descriptions of the same or similar components of the passive device 100E illustrated in FIGS. 12, 13A, and 13B, unless otherwise described.

In a similar manner to the example embodiment illustrated in FIG. 7, the passive device 100F according to some example embodiments may further have the active region 202, having a desired (and/or predetermined area), below the active pattern 205. The first and second conductivity-type impurity regions 205A and 205B of the active pattern 205 may respectively have regions extending to corresponding regions of the active region 202 in a vertical downward direction. The first and second contacts 280A′ and 280B′ may extend from a second surface of the substrate 201, and may be selected such that an end thereof is positioned within the active region 202 or the active pattern 205.

Referring to FIGS. 15A and 15B, the active pattern 205 may have a structure extending on the active region 202 in a first direction (for example, a direction of D1). The active region 202 may be understood as a structure provided from a portion of a semiconductor substrate (not illustrated).

In some example embodiments, the first and second contacts 280A′ and 280B′ may include a metal-semiconductor compound layer 283′ formed on the first and second conductivity-type impurity regions 205A and 205B, respectively. The first and second contacts 280A′ and 280B′ may improve contact resistance with the first and second conductivity-type impurity regions 205A and 205B using the metal-semiconductor compound layer 283′. For example, the metal-semiconductor compound layer 283′ may include cobalt silicide (CoSiₓ), nickel silicide (NiSiₓ), or manganese silicide (MnSiₓ), but the inventive concepts are not limited thereto.

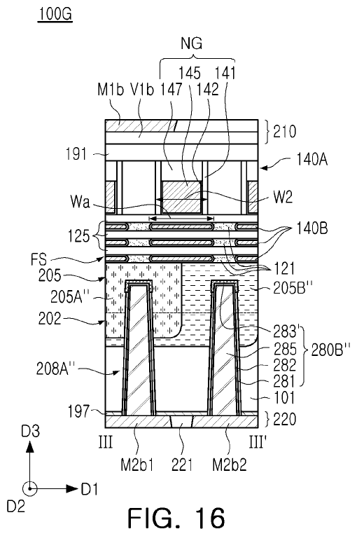

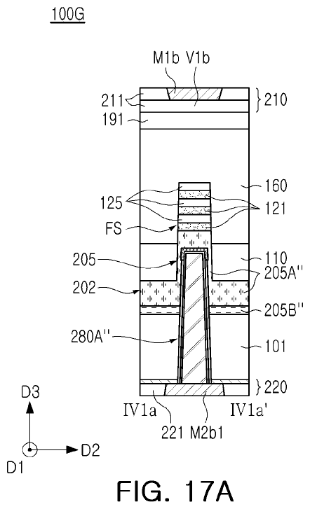

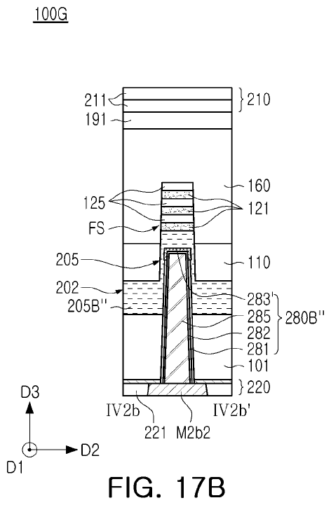

FIGS. 16, 17A, and 17B are cross-sectional views of a semiconductor device according to some example embodiments of the inventive concepts.

Referring to FIGS. 16, 17A, and 17B, a passive device 100G according to some example embodiments may be understood as being similar to the passive device 100E illustrated in FIGS. 12, 13A, and 13B, except that the active region 202 and a portion of a semiconductor substrate 101 remain below the active pattern 205, the metal-semiconductor compound layer 283′ is disposed on an upper end of the second contact 280B″, and the second contact 280B″ further includes an insulating liner 281 for electrical insulation from the semiconductor substrate 101. Other components may be understood with reference to descriptions of the same or similar components of the passive device 100E illustrated in FIGS. 12, 13A, and 13B, unless otherwise described.

In some example embodiments, not only the active region 202 but also another region 101 of the semiconductor substrate, that is, a region 101 of the semiconductor substrate that is not ion-implanted, may remain below the active pattern 205. In some example embodiments, the remaining semiconductor substrate 101 may replace an insulating substrate (for example, 201 in FIG. 4).

In some example embodiments, the second contact 280B″ may be configured to pass through the semiconductor substrate 101, and thus may further include an insulating liner 281 to provide electrical insulation from the semiconductor substrate 101. The second contact 280B″ may include a conductive plug 285, a conductive barrier 282 covering an upper surface and a side surface of the conductive plug 285, and an insulating liner 281 disposed between the conductive barrier 281 and at least the semiconductor substrate 101. The first and second contacts 280A″ and 280B″ according to some example embodiments may include a metal-semiconductor compound layer 283′ positioned on an upper end thereof, in a similar manner to the previous example embodiment (see FIG. 14).

According to some embodiments of FIGS. 12, 14, and 16, first and second contacts may be respectively changed to backside contacts directly connected to first and second conductivity-type impurity regions, and first or second conductive-type epitaxial patterns, causing various resistance elements, may be structurally omitted, thereby reducing an operating voltage and greatly improving a distribution of the operating voltage.

According to the above-described example embodiments, at least one of two contacts may be changed to a backside contact directly connected to a first or second conductivity-type impurity region. Such a change may limit and/or prevent the influence of a first or second conductivity-type epitaxial pattern causing various resistance elements, thereby reducing an operating voltage and greatly improving a distribution of the operating voltage.

While example embodiments have been shown and described above, it will be apparent to those skilled in the art that modifications and variations could be made without departing from the scope of the inventive concepts as defined by the appended claims.

What is claimed is:

1. A semiconductor device comprising:
a substrate having a first surface and a second surface opposing the first surface;
an active pattern on the first surface of the substrate, the active pattern extending in a first direction, the active pattern having a first conductivity-type impurity region and a second conductivity-type impurity region arranged along the first direction, the first conductivity-type impurity region and the second conductivity-type impurity region contacting each other;
semiconductor patterns stacked on a portion of the active pattern between the first and second conductivity-type impurity regions, the semiconductor patterns spaced apart from each other in a vertical direction;
an inactive gate structure extending across the portion of the active pattern between the first and second conductivity-type impurity regions of the active pattern in a second direction, the second direction intersecting the first direction, and the inactive gate structure surrounding the semiconductor patterns;
a first contact passing through the substrate from the second surface of the substrate, the first contact connected to the first conductivity-type impurity region; and
a second contact passing through the substrate from the second surface of the substrate, the second contact connected to the second conductivity-type impurity region.

2. The semiconductor device of claim 1, wherein the substrate includes an insulating material layer.

3. The semiconductor device of claim 2, wherein each of the first and second contacts includes a conductive plug, and a conductive barrier covering an upper surface and a side surface of the conductive plug.

4. The semiconductor device of claim 3, wherein
the first and second conductivity-type impurity regions respectively have first and second metal-semiconductor compound layers respectively on surfaces thereof, the surfaces of the first and second metal-semiconductor compound layers respectively contacting the first and second contacts, and
the conductive barriers of the first and second contacts are respectively between the first and second metal-semiconductor compound layers and the conductive plugs.

5. The semiconductor device of claim 1, wherein
the semiconductor patterns are respectively second semiconductor layers extending onto the active pattern on both sides of the inactive gate structure, and
the semiconductor device further includes first semiconductor layers between the active pattern and the second semiconductor layers on the active pattern on the both sides of the inactive gate structure, a composition of the first semiconductor layers being different than a composition of the second semiconductor layers.

6. The semiconductor device of claim 5, wherein
the inactive gate structure has a first portion on an uppermost semiconductor layer from among the second semiconductor layers, and second portions connected to the first portion, and the second portions are between the active pattern and the second semiconductor layers, and between each of the second semiconductor layers, and
a width of each of the second portions of the inactive gate structure in the first direction is greater than a width of the first portion of the inactive gate structure in the first direction.

7. The semiconductor device of claim 5, wherein the first and second semiconductor layers are not intentionally doped with conductivity-type impurities.

8. The semiconductor device of claim 1, further comprising:
an active region on the first surface of the substrate,
wherein the active pattern extends on the active region in the first direction, and
the first and second conductivity-type impurity regions of the active pattern respectively extend to corresponding regions of the active region.

9. The semiconductor device of claim 8, wherein
the first contact extends from the second surface of the substrate into the active region or the active pattern, and
the second contact extends from the second surface of the substrate into the active region or the active pattern.

10. The semiconductor device of claim 8, wherein
the substrate is a semiconductor substrate, and
each of the first and second contacts includes a conductive plug, a conductive barrier covering an upper surface and a side surface of the conductive plug, and an insulating liner between the conductive barrier and the substrate.

11. The semiconductor device of claim 1, wherein the inactive gate structure includes a gate electrode extending in the second direction and surrounding each of the semiconductor patterns, and a gate insulating film between the semiconductor patterns and the gate electrode.

12. A semiconductor device comprising:
a substrate having a first surface and a second surface opposing the first surface;
an active pattern on the first surface of the substrate, the active pattern extending in a first direction, the active pattern having a first conductivity-type impurity region and a second conductivity-type impurity region arranged along the first direction, the first conductivity-type impurity region and the second conductivity-type impurity region contacting each other;
semiconductor patterns stacked on a portion of the active pattern between the first and second conductivity-type impurity regions, the semiconductor patterns spaced apart from each other in a vertical direction;
an inactive gate structure extending across the portion of the active pattern between the first and second conductivity-type impurity regions in a second direction, the second direction intersecting the first direction, and the inactive gate structure surrounding the semiconductor patterns;
a first conductivity-type epitaxial pattern and a second conductivity-type epitaxial pattern respectively on both side surfaces of the semiconductor patterns in the first direction, the first conductivity-type epitaxial pattern and the second conductivity-type epitaxial pattern respectively on the first conductivity-type impurity region and the second conductivity-type impurity region of the active pattern;
an interlayer insulating layer on the first surface of the substrate, the interlayer insulating layer covering the first conductivity-type epitaxial pattern and the second conductivity-type epitaxial pattern;
a first contact passing through the interlayer insulating layer, the first contact connected to the first conductivity-type epitaxial pattern; and
a second contact passing through the substrate from the second surface of the substrate, the second contact connected to the second conductivity-type impurity region of the active pattern.

13. The semiconductor device of claim 12, further comprising:
an active region on the first surface of the substrate,
wherein the active pattern extends on the active region in the first direction, and
the first and second conductivity-type impurity regions of the active pattern respectively extend to corresponding regions of the active region.

14. The semiconductor device of claim 13, wherein
the substrate is a semiconductor substrate, and
the second contact includes a conductive plug, a conductive barrier covering an upper surface and a side surface of the conductive plug, and an insulating liner between the conductive barrier and the substrate.

15. The semiconductor device of claim 12, further comprising:
a first interconnection structure on the interlayer insulating layer, the first interconnection structure including a first interconnection layer connected to the first contact; and
a second interconnection structure on the second surface of the substrate, the second interconnection structure including a second interconnection layer connected to the second contact.

16. The semiconductor device of claim 12, wherein the semiconductor patterns are not intentionally doped with conductivity-type impurities.

17. A semiconductor device comprising:
a substrate having a first surface and a second surface opposing the first surface, and the substrate having a first device and a second device respectively on a first device region and a second device region of the first surface of the substrate,
wherein the first device includes
a first active pattern extending on the first surface of the substrate in a first direction;
first semiconductor patterns stacked on the first active pattern and spaced apart from each other in a vertical direction;
an active gate structure extending across the first active pattern in a second direction, the second direction intersecting the first direction, and the active gate structure surrounding the first semiconductor patterns; and
a pair of source/drain patterns on both sides of the first semiconductor patterns in the first direction, the pair of source/drain patterns respectively connected to both sides of the first semiconductor patterns; and
a gate structure extending in the second direction, the gate structure surrounding the first semiconductor patterns, the second device includes
a second active pattern extending on the first surface of the substrate in the first direction, the second active pattern having a first conductivity-type impurity region and a second conductivity-type impurity region arranged in the first direction, the first conductivity-type impurity region and the second conductivity-type impurity region contacting each other;
second semiconductor patterns stacked on a portion of the second active pattern between the first and second conductivity-type impurity regions, the second semiconductor patterns spaced apart from each other in the vertical direction;
an inactive gate structure extending across the portion of the second active pattern between the first and second conductivity-type impurity regions, the inactive gate structure surrounding the second semiconductor patterns; and
a first contact and a second contact respectively connected to the first conductivity-type impurity region and the second conductivity-type impurity region, and
at least one of the first and second contacts is respectively connected to the first and second conductivity-type impurity regions from the second surface of the substrate.

18. The semiconductor device of claim 17, wherein a width of the inactive gate structure of the second device in the first direction is greater than a width of the active gate structure of the first device in the first direction.

19. The semiconductor device of claim 17, wherein the first and second contacts pass through the substrate from the second surface of the substrate, and are respectively connected to the first and second conductivity-type impurity regions.

20. The semiconductor device of claim 17, wherein the second device further includes:
a first conductivity-type epitaxial pattern and a second conductivity-type epitaxial pattern respectively on both side surfaces of the second semiconductor patterns in the first direction, the first conductivity-type epitaxial pattern and the second conductivity-type epitaxial pattern respectively on the first conductivity-type impurity region and the second conductivity-type impurity region of the second active pattern; and
an interlayer insulating layer on the first surface of the substrate, the interlayer insulating layer covering the first conductivity-type epitaxial pattern and the second conductivity-type epitaxial pattern,
wherein the first contact passes through the interlayer insulating layer and is connected to the first conductivity-type epitaxial pattern, and the second contact passes through the substrate from the second surface of the substrate and is connected to the second conductivity-type impurity region.
